(19) United States
(12) Patent Application Publication
(10) Pub. No.: US 2005/0255664 A1
(43) Pub. Date: Nov. 17, 2005

(54) METHOD OF FORMING A METAL-INSULATOR-METAL CAPACITOR

(76) Inventors: Ching-Hung Kao, Hsin-Chu Hsien (TW); Anchor Chen, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/908,298

(22) Filed: May 5, 2005

Related U.S. Application Data
(66) Substitute for application No. 10/904,050, filed on Oct. 21, 2004, now abandoned.

(30) Foreign Application Priority Data
May 12, 2004 (CN) 2004100380026

(51) Int. Cl. H01G 4/008; H01L 21/20

(52) U.S. Cl. 438/396

(57) ABSTRACT

A method of forming a capacitor includes sequentially forming a barrier layer, a second dielectric layer, and a conductive layer on a surface of a first dielectric layer and conductors in the first dielectric layer, performing an etching process to remove portions of the barrier layer, the second dielectric layer, and the conductive layer to form the capacitor, and performing a contacting process to connect the conductive layer of the capacitor to a first terminal through a first contact plug.

### BACKGROUND OF INVENTION

1. Field of the Invention

The present invention relates to a method for forming a capacitor, and more particularly, to a method of forming a metal-insulator-metal capacitor (MIMC) applied in a copper process (Cu process).

2. Description of the Prior Art

Recently, the integrated circuit (IC) industry has developed continuously and flourishingly. The IC products, such as memory chips and central processing unit (CPU) chips that are popular from the early stage and communication chips that are popular and widely utilized in the age of mobile communication, are all developing towards powerful function, low price, and small size. In order to achieve the above-mentioned objectives, all of the manufacturers devote considerable manpower and material resources to expect a break-through in integration chip design and research in materials and processing. In the early stage, all of the metal interconnection lines are aluminum interconnection lines when fabricating various types of chips. However, the Cu process has become the main stream as the specifications of products become more and more rigorous. This is because the resistivity of copper is smaller than that of aluminum, and a large current can be sustained in a small area when utilizing the copper interconnection lines. Consequently, chips having reduced RC delay, improved metal interconnection line reliability, reduced layout area, and lower power consumption are fabricated. This tendency has become very obvious, especially as the development of Cu process related processes and equipment have matured.

Among all of the key components utilized in the IC products, capacitors are a very important kind of device. When forming a capacitor, both the material selection and processing quality will affect the capacitance value, the reliability performance, the dispersive behavior, and the radio frequency character (RF character) of the formed capacitor device to further affect the total performance of a chip. The RF character of a capacitor becomes even more important when the capacitor is applied in a communication chip. That is because a communication chip can actually be regarded as a radio frequency integrated chip (RF integrated chip) and is usually applied in a RF range. When the quality factor of a capacitor device is not stable enough, unexpected energy loss and noise occurs to result in unsatisfied chip performance.

Please refer to FIG. 1 to FIG. 5. FIG. 1 to FIG. 5 are schematic diagrams of a method for forming a capacitor 38 on a wafer 10 according to the prior art. As shown in FIG. 1, the prior art method for forming a capacitor on a wafer 10 is to provide the wafer 10 first, and the metal interconnection lines on the wafer 10 are formed by a Cu process, as mentioned previously. Since the structure on the wafer 10 varies according to the kind of formed chips, it is not mentioned specifically. In addition, the Cu process is a process having high contamination owing to the high penetration ability of Cu atoms. Therefore, capacitors are usually formed above a top level copper conductive line (Cu conductive line) 12. The Cu conductive line 12 is formed in a first dielectric layer 14. Actually, the Cu conductive line 12 and the first dielectric layer 14 are simultaneously formed by performing a chemical mechanical polishing (CMP) process. A first deposition process is then performed to form an isolation layer 16 on a surface of the wafer 10. The isolation layer 16, being a silicon nitride layer, covers the Cu conductive line 12 to prevent Cu atoms in the Cu conductive line 12 from diffusing upwards. A first conductive layer 18 is thereafter formed on a surface of the isolation layer 16. The first conductive layer 18 comprises a tantalum nitride layer (TaN layer) or a titanium nitride layer (TiN layer), and the first conductive layer 18 is formed by a sputtering process. After that, a photoresist layer (not shown) is coated on the first conductive layer 18. A first mask and a first photolithography process are then utilized to define the patterned photoresist layer that is used as a bottom electrode plate pattern 24.

As shown in FIG. 2, a first etching process is thereafter performed to etch the first conductive layer 18 until reaching the surface of the isolation layer 16, by utilizing the bottom electrode plate pattern 24 as a mask, to form a bottom electrode plate 26 of the capacitor (not shown). After that, a second deposition process is performed after removing the bottom electrode plate pattern 24 to form a second dielectric layer 28 on the surface of the wafer 10, as shown in FIG. 3. The second dielectric layer 28 comprises a silicon oxide layer or a silicon nitride layer, and the second dielectric layer 28 covers the bottom electrode plate 26. A second conductive layer 32 is then formed on a surface of the second dielectric layer 28. The second conductive layer 32 comprises a tantalum nitride layer or a titanium nitride layer, and the second conductive layer 32 is formed by another sputtering process. Another photoresist layer (not shown) is thereafter coated on the second conductive layer 32. After that, a second mask and a second photolithography process are utilized to define the patterned photoresist layer that is used as a top electrode plat pattern 34.

As shown in FIG. 4, a second etching process is then performed to etch the second conductive layer 32 and the second dielectric layer 28 until reaching the surface of the first conductive layer 18, by utilizing the top electrode plate pattern 34 as a mask, to form a top electrode plate 38 and a capacitor dielectric layer 42 of the capacitor 36. The fabrication of the capacitor 36 is thus completed. A third deposition process is thereafter performed, after removing the top electrode plate pattern 34, to form a third dielectric layer 44 on the surface of the wafer 10, as shown in FIG. 5. The third dielectric layer 44 covers the capacitor 36. After that, a contacting process is performed to form a first contact plug 46 and a second contact plug 48 in the third dielectric layer 44 such that the top electrode plate 38 of the capacitor 36 is connected to a first terminal 52 through the first contact plug 46 and the bottom electrode plate 26 of the capacitor 36 is connected to a second terminal 54 through the second contact plug 48. Actually, the first terminal 52 and the second terminal 54 are different aluminum bonding pads used for electrically connecting different potentials.

The prior art method of forming the capacitor requires two masks to define the top and bottom electrode plate patterns. That means, two photolithography processes and two etching processes are required, making the processing very long. The cost is thus raised. In addition, the yield is sometimes decreased due to complex process steps to affect the performance of the formed chip. Furthermore, the performance of the capacitor is improved when the resistivity values of the top and the bottom electrode plates are low in considering the character of the capacitor. That means, it is not a good selection to utilize tantalum nitride or titanium nitride as a material to form the top and bottom electrode plates. It is an advantage of the Cu metal interconnection lines that they have a very low resistivity value. However, it is impossible to use a portion of the Cu metal interconnection line structure as a portion of the electrode plate owing to the diffusion problem of the Cu atoms.

Therefore, it is very important to develop a new method of forming a metal-insulator-metal capacitor that uses the copper metal layer as a portion of the electrode plate and has superior performance. In addition, the method should not require two photolithography processes and two etching processes. Or two photolithography processes and two etching processes are required in the method of forming a metal-insulator-metal capacitor to form the metal-insulator-metal capacitor having another advantage, such as a high capacitance value.

### SUMMARY OF INVENTION

It is therefore a primary objective of the claimed invention to provide a method of forming a capacitor, especially a method of forming a metal-insulator-metal capacitor applied in a copper process to resolve the above-mentioned problem.

According to the claimed invention, a method for forming at least a capacitor on a semiconductor substrate is provided. At least a first dielectric layer and at least a conductor disposed in the first dielectric layer are included on a surface of the semiconductor substrate. The method comprises the following steps. First, a barrier layer, a second dielectric layer, and a conductive layer are sequentially formed on the surface of the semiconductor substrate. The barrier layer is directly in contact with the conductor. An etching process is performed to remove portions of the barrier layer, the second dielectric layer, and the conductive layer. The patterned barrier layer, the patterned second dielectric layer, and the patterned conductive layer constitute the capacitor. A contacting process is performed to connect the conductive layer in the capacitor to a first terminal through a first contact plug.

In the claimed invention, the method of forming the capacitor uses the Cu conductive line and the barrier layer as the bottom electrode plate of the capacitor. Since portions or the Cu conductive line are exposed, the Cu conductive line is successfully connected to the terminal. Therefore, the fabrication of the capacitor is completed by performing only one photolithography process and only one etching process. As a result, the process flow is shortened. At the same time, the capacitor having superior performance is fabricated because the Cu conductive line is a portion of the bottom electrode plate. Moreover, cost is reduced and the yield is increased. In addition, the capacitor having a high capacitance value is fabricated when preserving the two photolithography processes and two etching processes, which are utilized in the prior art method, to make the design of capacitor more flexible. When applying the present invention method to form capacitors on a specific chip, the performance of the chip is improved.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 to FIG. 5 are schematic diagrams of a method for forming a capacitor on a wafer according to the prior art.

FIG. 6 to FIG. 9 are schematic diagrams of a method for forming a capacitor on a wafer according to a first preferred embodiment of the present invention.

FIG. 10 to FIG. 15 are schematic diagrams of a method for forming a capacitor on a wafer according to a second preferred embodiment of the present invention.

FIG. 16 is an equivalent circuit diagram of the capacitor shown in FIG. 13.

FIG. 17 is a schematic diagram of a method for forming a capacitor on a wafer according to a third preferred embodiment of the present invention.

FIG. 18 is a schematic diagram of a method for forming a capacitor on a wafer according to a fourth preferred embodiment of the present invention.

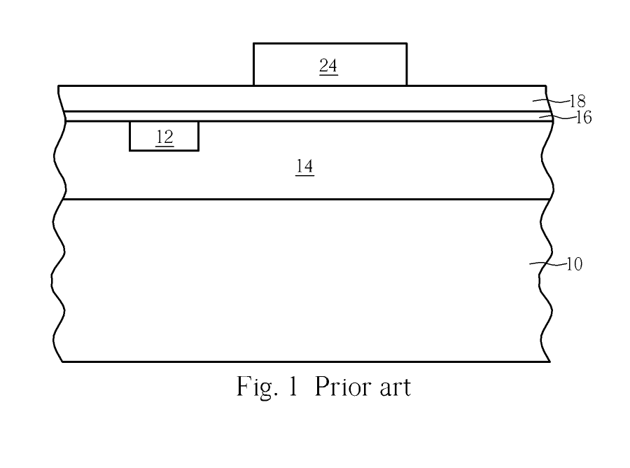

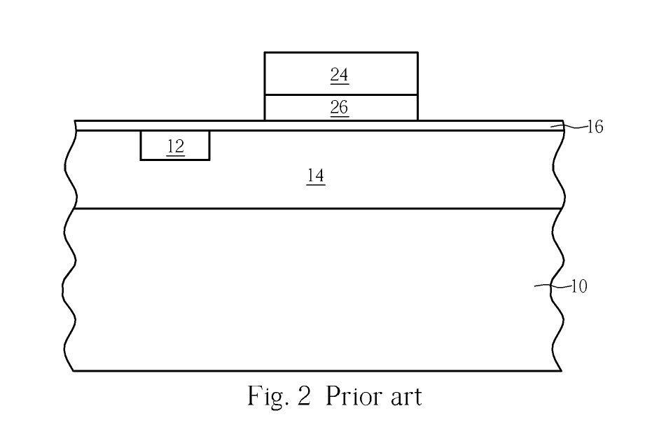

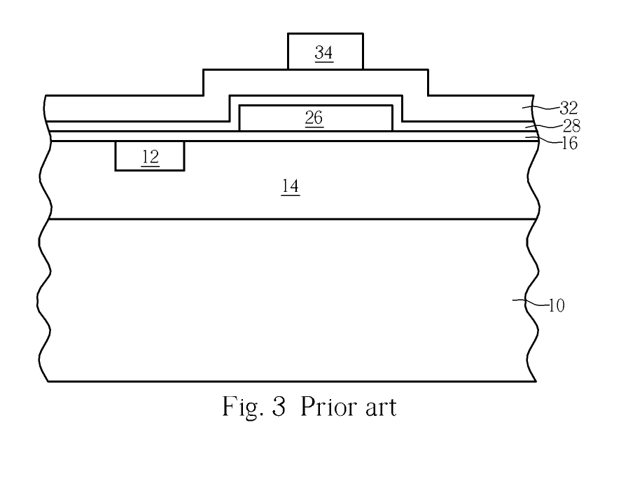

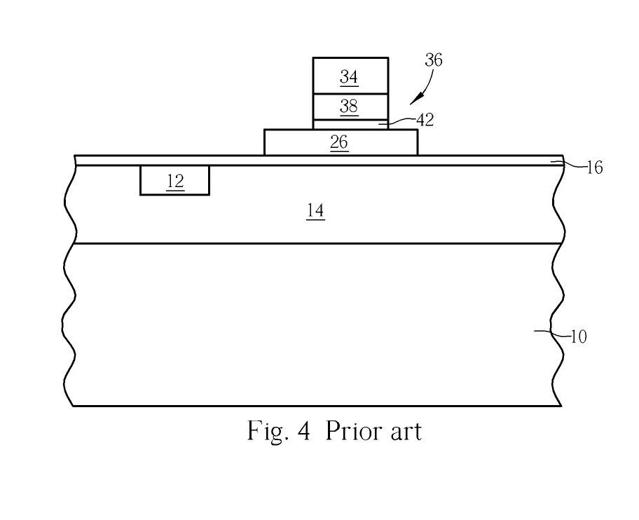

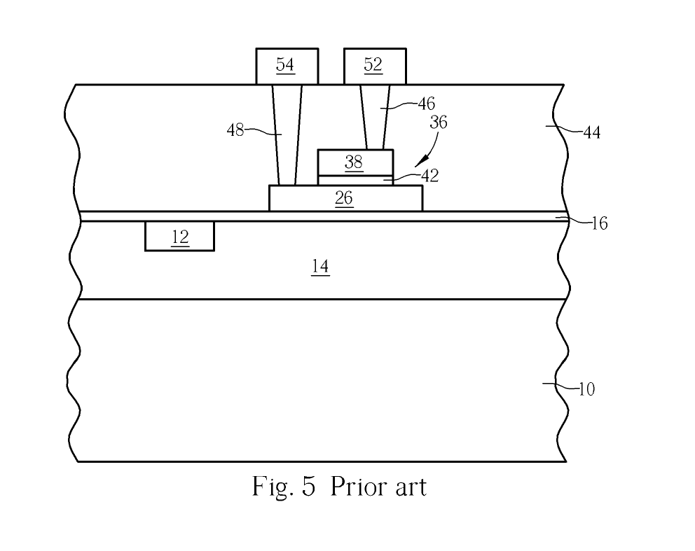

### DETAILED DESCRIPTION

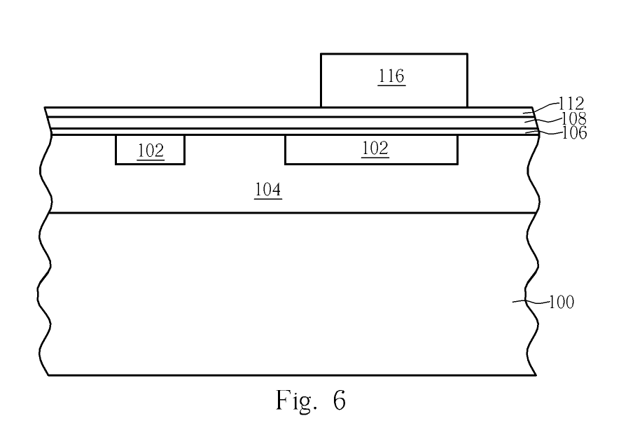

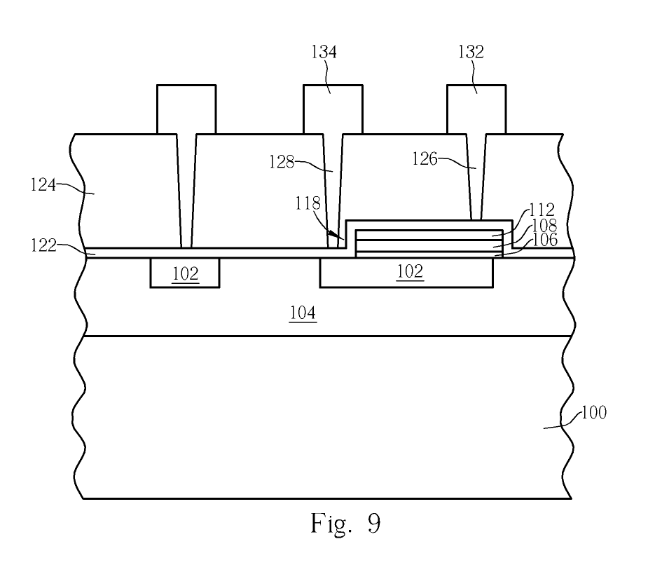

Please refer to FIG. 6 to FIG. 9. FIG. 6 to FIG. 9 are schematic diagrams of a method for forming a capacitor 118 on a wafer 100 according to a first preferred embodiment of the present invention. As shown in FIG. 6, the present invention method for forming a capacitor on a wafer 100 first provides the wafer 100, and the metal interconnection lines on the wafer 100 are formed by a Cu process. Since the structure on the wafer 100 varies according to the kind of formed chips, it is not mentioned specifically. In FIG. 6 to FIG. 9, only at least a top level Cu conductive line 102 is shown. The Cu conductive line 102 is formed in a first dielectric layer 104. Actually, the Cu conductive line 102 and the first dielectric layer 104 are simultaneously formed by a CMP process. A barrier layer 106, a second dielectric layer 108, and a conductive layer 112 are thereafter sequentially formed on a surface of the wafer 100, and the barrier layer 106 is directly in contact with the Cu conductive line 102.

The barrier layer 106 comprises a tantalum nitride layer, a tantalum layer (Ta layer), or a titanium nitride layer, and is formed by a sputtering process. The second dielectric layer 108 comprises a silicon oxide layer, a silicon nitride layer, or a high dielectric constant (high-k) material layer. The conductive layer 112 comprises a tantalum nitride layer or a titanium nitride layer, and is formed by another sputtering process. After that, a photoresist layer (not shown) is coated on the conductive layer 112. A mask (not shown) and a photolithography process are then utilized to define the patterned photoresist layer that is used as a capacitor pattern 116.

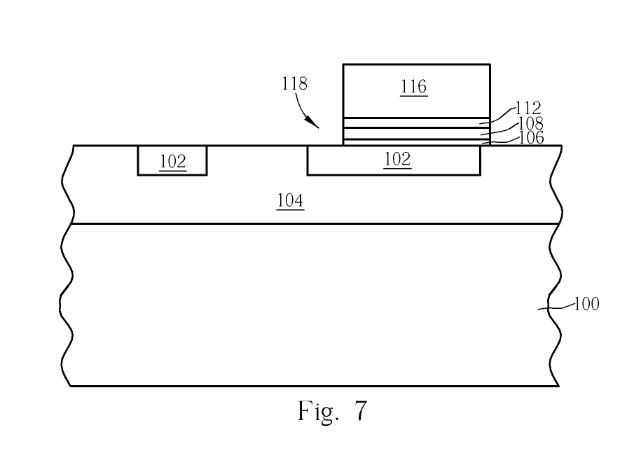

As shown in FIG. 7, an etching process is then performed to remove portions of the barrier layer 106, the second dielectric layer 108, and the conductive layer 112. The Cu conductive line 102, the patterned barrier layer 106, the patterned second dielectric layer 108, and the patterned conductive layer 112 therefore constitute a capacitor 118. The patterned barrier layer 106 and the Cu conductive line 102 constitute a bottom electrode plate of the capacitor 118. The patterned second dielectric layer 108 is a capacitor dielectric layer of the capacitor 118. The patterned conductive layer 112 is a top electrode plate of the capacitor 118. The capacitor 118 is thus a metal-insulator-metal capacitor. It is worth noting that the patterned barrier layer 106, the patterned second dielectric layer 108, and the patterned conductive layer 112 expose portions of the Cu conductive line 102 so that the Cu conductive line 102 can be successfully connected to a terminal (not shown) in a subsequent contacting process. In addition, the barrier layer 106, formed on the Cu conductive line 102 according to the present invention, is used for preventing Cu atoms in the Cu conductive line 102 from diffusing and is used as a portion of the bottom electrode plate. It is worth noting that the patterned barrier layer 106 nearly covers the entire Cu conductive line 102 in this preferred embodiment. Under the circumstances, the contact between the Cu conductive line 102 and the patterned barrier layer 106 is excellent, and the area of the capacitor electrode plate is larger. This preferred embodiment thus illustrates a better means to practice the present invention.

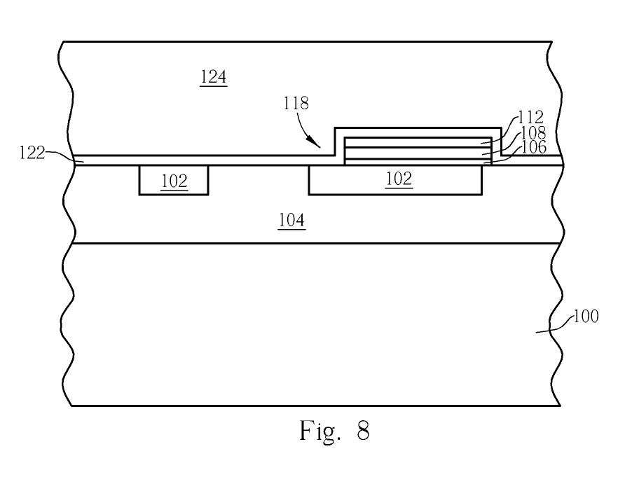

A deposition process is thereafter performed, after removing the capacitor pattern 116, to sequentially form an isolation layer 122 and a third dielectric layer 124 on the surface of the wafer 100, as shown in FIG. 8. The isolation layer 122 and the third dielectric layer 124 cover the capacitor 118 and Cu conductive line 102. The isolation layer 122 is usually a silicon nitride layer for preventing Cu atoms in the Cu conductive line 102 from diffusing upwardly.

After that, a contacting process is performed to form a first contact plug 126 and a second contact plug 128 in the third dielectric layer 124 and the isolation layer 122. The conductive layer 112 in the capacitor 118 is therefore connected to an aluminum bonding pad 132 through the first contact plug 126, and the Cu conductive line 102 is therefore connected to another aluminum bonding pad 134 through the second contact plug 128. Actually, the bonding pads 132, 134 are used as terminals to pass different potentials applied on them to the top and bottom electrode plates of the capacitor 118 during operation. Since the Cu conductive wire 102 is a portion of the bottom electrode plate of the capacitor 118, it may be electrically connected to a corresponding potential directly through the layout to omit the fabrication of the second contact plug 128 and the aluminum bonding pad 134. Furthermore, the contact process in this preferred embodiment can be regarded as a single damascene process. Because the practice of this process is well known by those skilled in the art, it is not mentioned redundantly.

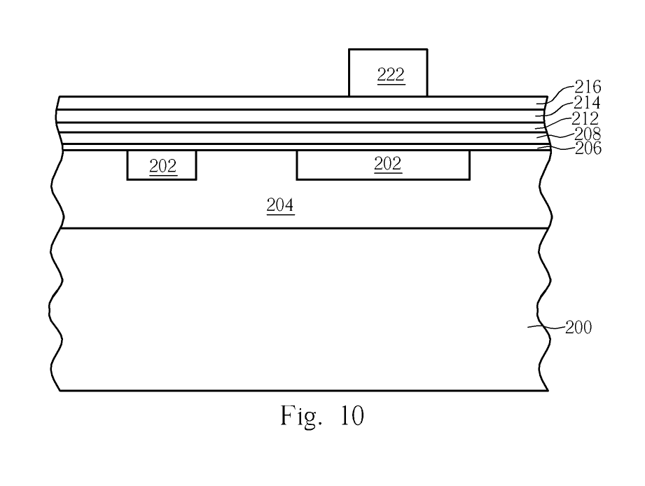

In the first preferred embodiment of the present invention, only one mask is utilized to define the capacitor pattern. In other words, only one photolithography process and etching process are utilized to shorten the whole processing. In a second preferred embodiment of the present invention, two photolithography processes and etching processes are preserved to form a capacitor having a high capacitance value. Please refer to FIG. 10 to FIG. 15. FIG. 10 to FIG. 15 are schematic diagrams of a method for forming a capacitor 234 on a wafer 200 according to a second preferred embodiment of the present invention. As shown in FIG. 10, the present invention method for forming a capacitor on a wafer 200 is to provide the wafer 200 first, and the metal interconnection lines on the wafer 200 are formed by a Cu process. Since the structure on the wafer 200 varies according to the kind of formed chips, it is not mentioned specifically. In FIG. 10 to FIG. 15, only at least a top level Cu conductive line 202 is shown. The Cu conductive line 202 is formed in a first dielectric layer 204. Actually, the Cu conductive line 202 and the first dielectric layer 204 are simultaneously formed by a CMP process. A barrier layer 206, a second dielectric layer 208, a first conductive layer 212, a third dielectric layer 214, and a second conductive layer 216 are thereafter sequentially formed on a surface of the wafer 200, and the barrier layer 206 is directly in contact with the Cu conductive line 202.

The barrier layer 206 comprises a tantalum nitride layer, a tantalum layer, or a titanium nitride layer, and is formed by a sputtering process. Both the second dielectric layer 208 and the third dielectric layer 214 comprise a silicon oxide layer, a silicon nitride layer, or a high dielectric constant material layer. Both the first conductive layer 212 and the second conductive layer 216 comprise a tantalum nitride layer or a titanium nitride layer, and are formed by another sputtering process. After that, a photoresist layer (not shown) is coated on the second conductive layer 216. A first mask (not shown) and a first photolithography process are then utilized to define the patterned photoresist layer that is used as a first pattern 222.

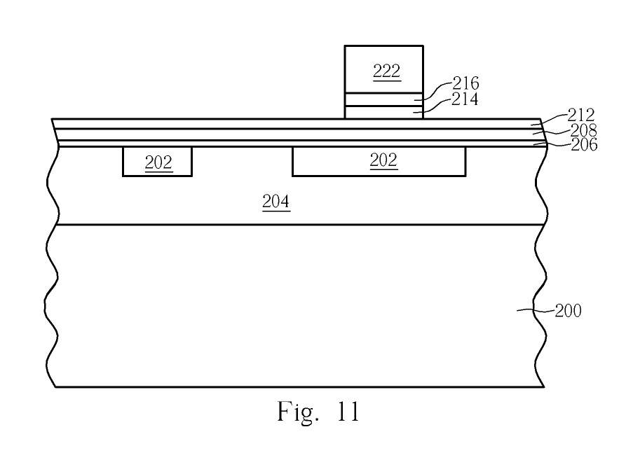

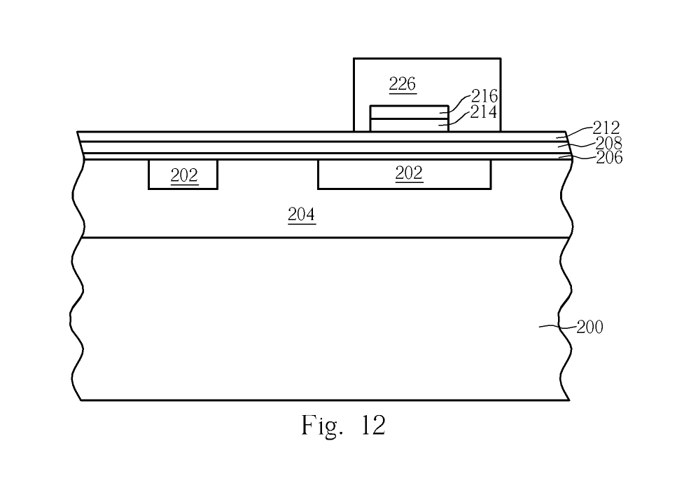

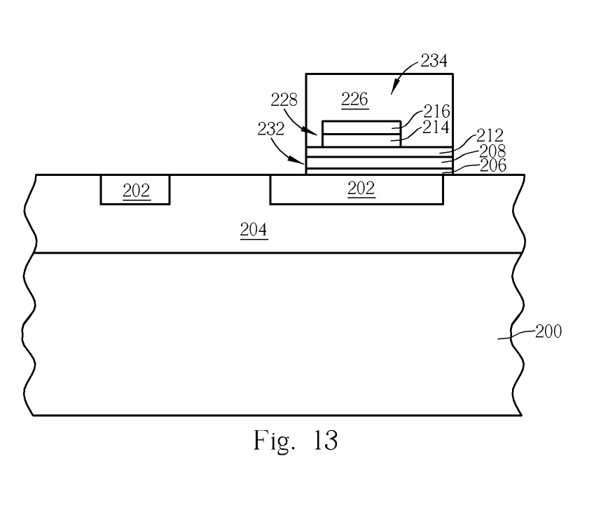

As shown in FIG. 11, a first etching process is then performed to etch the second conductive layer 216 and the third dielectric layer 214 until reaching a surface of the first conductive layer 212, by utilizing the first pattern 222 as a mask. A photoresist layer (not shown) is thereafter coated on the surface of the wafer 200 after removing the first pattern 222, as shown in FIG. 12. After that, a second mask (not shown) and a second photolithography process are utilized to define the patterned photoresist layer that is used as a second pattern 226. As shown in FIG. 13, a second etching process is then performed to etch the first conductive layer 212, the second dielectric layer 208, and the barrier layer 206 until reaching a surface of the Cu conductive line 202 and the first dielectric layer 204, by utilizing the second pattern 226 as a mask. The patterned first conductive layer 212, the patterned third dielectric layer 214, and the patterned second conductive layer 216 constitute a first capacitor 228, and the patterned first conductive layer 212, the patterned second dielectric layer 208, and the patterned barrier layer 206 constitute a second capacitor 232. The first capacitor 228 and the second capacitor 232 are connected in parallel to generate an equivalent capacitor 234.

It is worth noting that the patterned second conductive layer 216 and the patterned third dielectric layer 214 expose portions of the patterned first conductive layer 212, and the patterned second conductive layer 216, the patterned third dielectric layer 214, the patterned first conductive layer 212, the patterned second dielectric layer 208, and the patterned barrier layer 206 expose portions of the Cu conductive line 202, after performing the second etching process, by pre-designing the first mask (not shown) and the second mask (not shown). Therefore, the Cu conductive line 202 and the first conductive layer 212 can be successfully connected to a terminal (not shown) in a subsequent contacting process. In addition, the barrier layer 206, formed on the Cu conductive line 202 according to the present invention, is used for preventing Cu atoms in the Cu conductive line 202 from diffusing and is used as a portion of the bottom electrode plate of the second capacitor 232. It is worth noting that the patterned barrier layer 206 nearly covers the entire Cu conductive line 202 in this preferred embodiment. Under the circumstances, the contact between the Cu conductive line 202 and the patterned barrier layer 206 is excellent, and the area of the capacitor electrode plate is larger. This preferred embodiment thus illustrates a better means to practice the present invention.

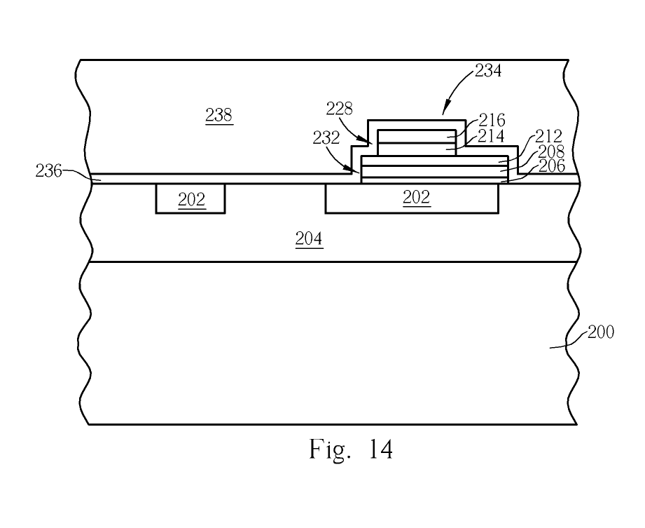

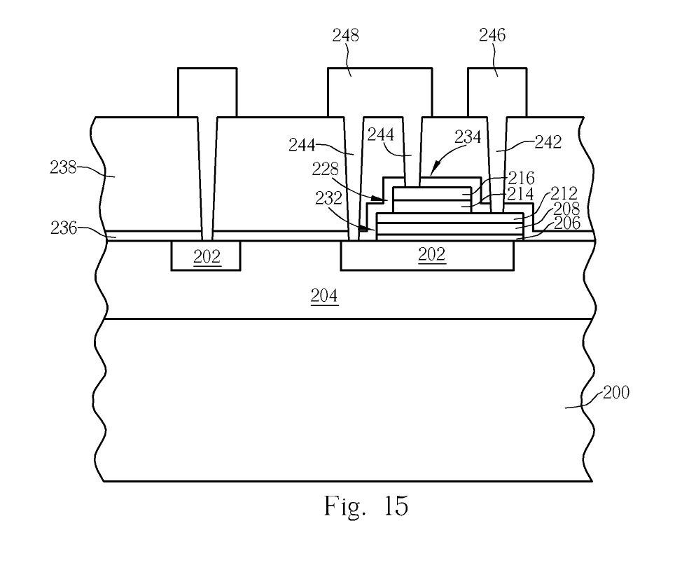

As shown in FIG. 14, a deposition process is then performed, after removing the second pattern 226, to sequentially form an isolation layer 236 and a fourth dielectric layer 238 on the surface of the wafer 200. The isolation layer 236 and the fourth dielectric layer 238 cover the first capacitor 228, the second capacitor 232, and the Cu conductive line 202. The isolation layer 236 is usually a silicon nitride layer for preventing Cu atoms in the Cu conductive line 202 from diffusing upwardly. As shown in FIG. 15, a contacting process is thereafter performed to form a first contact plug 242 and a second contact plug 244 in the fourth dielectric layer 238 and the isolation layer 236. The first conductive layer 212 in the first capacitor 228 is therefore connected to an aluminum bonding pad 246 through the first contact plug 242, and the second conductive layer 216 in the first capacitor 228 and the Cu conductive line 202 are therefore connected to another aluminum bonding pad 248 through the second contact plug 244. Actually, the bonding pads 246, 248 are used as terminals to pass different potentials applied on them to the top and bottom electrode plates of the first capacitor 228 and the second capacitor 232 during operation. Furthermore, the contacting process in this preferred embodiment can be regarded as a single damascene process.

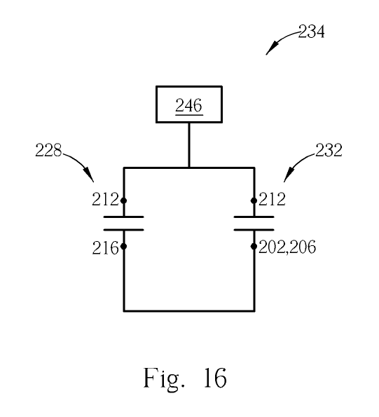

Please refer to FIG. 16. FIG. 16 is an equivalent circuit diagram of the capacitor 234 shown in FIG. 13. As shown in FIGS. 13, 15, and 16, the capacitor 234, shown in FIG. 13, is the equivalent capacitor including the first capacitor 228 and the second capacitor 232, shown in FIG. 13, connected in parallel with each other. The patterned first conductive layer 212 is a top plate of the first capacitor 228 and the second capacitor 232. The patterned third dielectric layer 214 is a capacitor dielectric layer of the first capacitor 228. The patterned second dielectric layer 208 is a capacitor dielectric layer of the second capacitor 232. The patterned second conductive layer 216 is a bottom electrode plate of the first capacitor 228. The patterned barrier layer 206 and the Cu conductive line 202 constitute a bottom electrode plate of the second capacitor 232. Both the first capacitor 228 and the second capacitor 232 are thus metal-insulator-metal capacitors. The top electrode plates of the first capacitor 228 and the second capacitor 232 (the first conductive layer 212) are electrically connected to the aluminum bonding pad 246 through the first contact plug 242. The bottom electrode plate of the first capacitor 228 (the second conductive layer 216) is electrically connected to the bottom electrode plate (constituted by the patterned barrier layer 206 and the Cu conductive line 202) of the second capacitor 232 through the second contact plug 244. As a result, the capacitance value (C) of the capacitor 234 is equal to the sum of the capacitance value (C₁) of the first capacitor 228 and the capacitance value (C₂) of the second capacitor 232. In this preferred embodiment, the capacitance value of the capacitor 234 is up to two times the capacitance value of a single capacitor if the first capacitor 228 and the second capacitor 232 are formed from the same materials. However, adjusting the materials used in the first capacitor 228 and the second capacitor 232 can further increase the capacitance value of the capacitor 234.

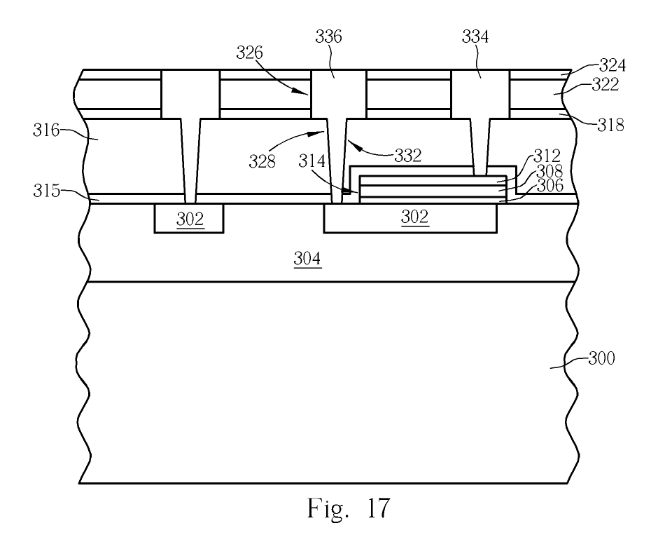

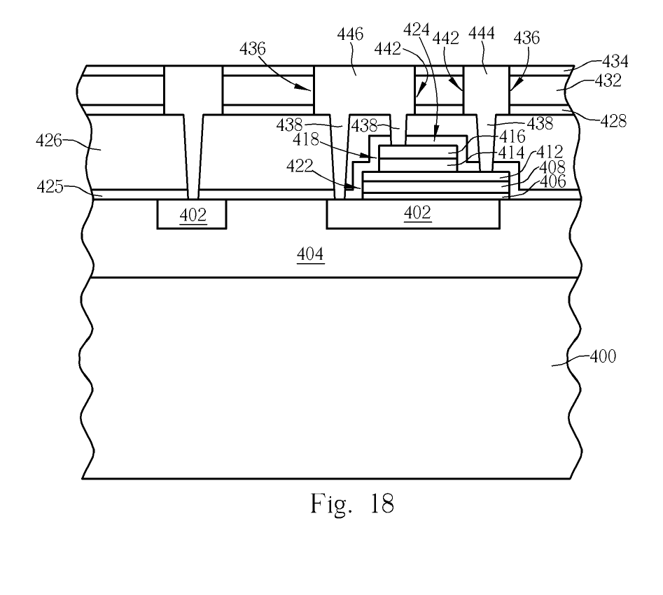

As mentioned previously, the capacitor according to the prior art is usually formed above the top level Cu conductive line because the penetration ability of Cu atoms is very strong and thus makes the Cu process a high contamination process. However, the Cu conductive line and the barrier layer are used as an electrode plate of the capacitor, and the isolation layer is immediately formed after completing the etching process for the capacitor to cover the capacitor and the Cu conductive line to prevent Cu atoms in the Cu conductive line from diffusing out, according to the present invention. Therefore, the capacitor can be formed between each two adjacent levels of the Cu interconnection lines according to the present invention. Please refer to FIG. 17 and FIG. 18. FIG. 17 is a schematic diagram of a method for forming a capacitor 314 on a wafer 300 according to a third preferred embodiment of the present invention. FIG. 18 is a schematic diagram of a method for forming a capacitor 424 on a wafer 400 according to a fourth preferred embodiment of the present invention. As shown in FIG. 17, a wafer 300 is provided first. At least a Cu conductive line 302 is included on the wafer 300. The Cu conductive line 302 is formed in a first dielectric layer 304 and the Cu conductive line 302 is not the top level Cu conductive line. A capacitor 314, constituted by a barrier layer 306, a second dielectric layer 308, and a conductive layer 312, is then formed on a surface of the wafer 300. The barrier layer 306 is directly in contact with the Cu conductive line 302. An isolation layer 315 is thereafter formed followed by the formation of a next level Cu interconnection line after the fabrication of the capacitor 314. The method for forming the next level Cu interconnection line, being the same as the prior art method, is mentioned as follows. A silicon oxide layer 316 is deposited first followed by a CMP process to level it. A silicon nitride layer or a silicon oxynitride layer used as a stop layer 318, another silicon oxide layer 322, and a silicon nitride layer or a silicon oxynitride layer used as another stop layer 324 are thereafter sequentially deposited. After that, a two-stage etching process is performed to form trences 326 on top of via holes 328. Later, the trenches 326 and the via holes 328 are filled with copper. Finally. another CMP process is performed to remove copper positioned outside the trenches 326 and the via holes 328 to complete the fabrication of dual damascene structures 322. In this preferred embodiment, the conductive layer 312 in the capacitor 314 is connected to a Cu conductive line 334, and the Cu conductive line 302 is connected to another Cu conductive line 336.

As shown in FIG. 18, a wafer 400 is provided first. At least a Cu conductive line 402 is included on the wafer 400. The Cu conductive line 402 is formed in a first dielectric layer 404 and the Cu conductive line 402 is not the top level Cu conductive line. A first capacitor 418, constituted by a first conductive layer 412, a third dielectric layer 414, and a second conductive layer 416, and a second capacitor 422, constituted by the first conductive layer 412, a second dielectric layer 408, and a barrier layer 406, are then formed on a surface of the wafer 400. The barrier layer 406 is directly in contact with the Cu conductive line 402. The first capacitor 418 and the second capacitor 422 are connected in parallel with each other to generate an equivalent capacitor 424. An isolation layer 425 is thereafter formed followed by the formation of a next level Cu interconnection line after the fabrication of the capacitor 424. The method for forming the next level Cu interconnection line, being the same as the prior art method, is mentioned as follows. A silicon oxide layer 426 is deposited first followed by a CMP process to level it. A silicon nitride layer or a silicon oxynitride layer used as a stop layer 428, another silicon oxide layer 432, and a silicon nitride layer or a silicon oxynitride layer used as another stop layer 434 are thereafter sequentially deposited. After that, a two-stage etching process is performed to form trenches 436 on top of via holes 438. Later, the trenches 436 and the via holes 438 are filled with copper. Finally, another CMP process is performed to remove copper positioned outside the trenches 436 and the via holes 438 to complete the fabrication of dual damascene structures 442. In this preferred embodiment, the conductive layer 412 in the first capacitor 418 is connected to a Cu conductive line 444, and the second conductive layer 416 in the first capacitor 418 and the Cu conductive line 402 are connected to another Cu conductive line 446.

In addition, the size, shape, and site of the electrode plate of the capacitor according to the present invention can be adjusted depending on the practical situation. The present invention method is feasible when portions of the Cu conductive line are exposed to allow the Cu conductive line to be successfully connected to a terminal. Therefore, any method utilizing this idea is within the scope of the present invention. However, issues, such as the contact resistivity between the barrier layer and the Cu conductive line, the misalignment occurring during processing, and overall performance of the capacitor, must be considered when practicing. Moreover, the present invention method works on any copper structure. For example, not only the Cu conductive line and the barrier layer may constitute the bottom electrode plate of the capacitor, but also the copper landing pad and the barrier layer may constitute the bottom electrode plate of the capacitor.

Since the method of forming the capacitor according to the present invention is to use the Cu conductive line and the barrier layer as the bottom electrode plate of the capacitor, the capacitor pattern can be defined by utilizing only one mask when portions or the Cu conductive line are exposed, and the Cu conductive line is successfully connect to the terminal. That means, the fabrication of the capacitor can be completed by performing only one photolithography process and only one etching process. The whole process flow is thus shortened. In addition, the capacitor having a high capacitance value is fabricated by performing two photolithography processes and two etching processes in the second preferred embodiment. When applying the present invention method to a practical production line, capacitors having low cost, high yield, and superior performance are formed.

In comparison with the prior art method of forming the capacitor, the method of forming the capacitor according to the present invention uses the Cu conductive line and the barrier layer as the bottom electrode plate of the capacitor. Since portions or the Cu conductive line are exposed, the Cu conductive line is successfully connected to the terminal. Therefore, the fabrication of the capacitor can be completed by performing only one photolithography process and only one etching process. Not only is the process flow shortened, but also the capacitor having superior performance is fabricated because the Cu conductive line is a portion of the bottom electrode plate. Furthermore, cost is reduced and the yield is increased. Moreover, the capacitor having a high capacitance value is fabricated when preserving the two photolithography processes and two etching processes, which are utilized in the prior art method, to make the design of capacitor more flexible. When applying the present invention method to form capacitors on a specific chip, the performance of the chip is improved.

Those skilled in the art will readily observe that numerous modifications and alterations of the device may be made while retaining the teachings of the invention. Accordingly, the above disclosure should be construed as limited only by the metes and bounds of the appended claims.

1. A method for forming at least a capacitor on a semiconductor substrate, at least a first dielectric layer and at least a conductor disposed in the first dielectric layer being included on a surface of the semiconductor substrate, the method comprising:
sequentially forming a barrier layer, a second dielectric layer, and a conductive layer on the surface of the semiconductor substrate, the barrier layer being directly in contact with the conductor;
performing an etching process to remove portions of the barrier layer, the second dielectric layer, and the conductive layer, the patterned barrier layer, the patterned second dielectric layer, and the patterned conductive layer constituting the capacitor; and
performing a contacting process to connect the conductive layer in the capacitor to a first terminal through a first contact plug.

2. The method of claim 1 wherein the capacitor is a metal-insulator-metal capacitor (MIMC).

3. The method of claim 1 wherein the conductor is formed by a copper process, and the barrier layer is used for preventing copper atoms in the conductor from diffusing.

4. The method of claim 3 wherein the barrier layer comprises a tantalum layer (Ta layer), a tantalum nitride layer (TaN layer), or a titanium nitride layer (TiN layer).

5. The method of claim 3 wherein the conductor is a portion of a bottom electrode of the capacitor.

6. The method of claim 5 wherein the conductor covered by the patterned barrier layer is a portion of the bottom electrode.

7. The method of claim 1 wherein the second dielectric layer comprises a silicon oxide layer, a silicon nitride layer, or a high dielectric constant (high-k) material layer.

8. The method of claim 1 wherein the conductive layer comprises a titanium nitride layer (TiN layer) or a tantalum nitride layer (TaN layer).

9. The method of claim 1 wherein a deposition process is performed after performing the etching process to sequentially form an isolation layer and a third dielectric layer on the surface of the semiconductor substrate.

10. The method of claim 1 wherein the conductor is electrically connected to a second terminal.

11. The method of claim 10 wherein a second contact plug is formed when performing the contacting process to connect the conductor to the second terminal through the second contact plug.

12. The method of claim 1 wherein the first terminal comprises an aluminum (Al) bonding pad or a copper wire.

13. The method of claim 12 wherein the contacting process comprises a single damascene process or a dual damascene process.

14. A method for forming at least a capacitor on a semiconductor substrate, at least a first dielectric layer and at least a conductor disposed in the first dielectric layer being included on a surface of the semiconductor substrate, the method comprising:
sequentially forming a barrier layer, a second dielectric layer, a first conductive layer, a third dielectric layer, and a second conductive layer on the surface of the semiconductor substrate, the barrier layer being directly in contact with the conductor;
performing a first etching process to remove portions of the second conductive layer and the third dielectric layer;
performing a second etching process to remove portions of the first conductive layer, the second dielectric layer, and the barrier layer, the patterned first conductive layer, the patterned third dielectric layer, and the patterned second conductive layer constituting a first capacitor, the patterned first conductive layer, the patterned second dielectric layer, and the patterned barrier layer constituting a second capacitor; and
performing a contacting process to connect the first conductive layer in the first capacitor to a first terminal through a first contact plug, and to connect the second conductive layer in the first capacitor and the conductor to a second terminal through a second contact plug.

15. The method of claim 14 wherein both the first capacitor and the second capacitor are metal-insulator-metal capacitors (MIMC).

16. The method of claim 14 wherein the conductor is formed by a copper process, and the barrier layer is used for preventing copper atoms in the conductor from diffusing.

17. The method of claim 16 wherein the barrier layer comprises a tantalum layer (Ta layer), a tantalum nitride layer (TaN layer), or a titanium nitride layer (TiN layer).

18. The method of claim 16 wherein the conductor is a portion of a bottom electrode of the second capacitor.

19. The method of claim 18 wherein the conductor covered by the patterned barrier layer is a portion of the bottom electrode.

20. The method of claim 14 wherein both the second dielectric layer and the third dielectric layer comprise a silicon oxide layer, a silicon nitride layer, or a high dielectric constant (high-k) material layer.

21. The method of claim 14 wherein both the first conductive layer and the second conductive layer comprise a titanium nitride layer (TiN layer) or a tantalum nitride layer (TaN layer).

22. The method of claim 14 wherein the patterned second conductive layer and the patterned third dielectric layer expose portions of the patterned first conductive layer.

23. The method of claim 14 wherein a deposition process is performed after performing the etching process to sequentially form an isolation layer and a fourth dielectric layer on the surface of the semiconductor substrate.

24. The method of claim 14 wherein both the first terminal and the second terminal comprise an aluminum (Al) bonding pad or a copper wire.

25. The method of claim 24 wherein the contacting process comprises a single damascene process or a dual damascene process.
